(19) United States
(12) Patent Application Publication
(10) Pub. No.: US 2003/0229836 A1
(43) Pub. Date: Dec. 11, 2003

(54) Integrated circuit

(75) Inventor: Kazuhiro Matsumoto, Chino-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/370,284

(22) Filed: Feb. 18, 2003

(30) Foreign Application Priority Data
Feb. 22, 2002 (JP) 2002-046298
Jan. 29, 2003 (JP) 2003-020435

(51) Int. Cl. G06F 11/00; G01R 31/28

(52) U.S. Cl. 714/736

(57) ABSTRACT

An integrated circuit includes a plurality of data processing circuits that perform an identical processing operation and a judging circuits that judges a consistency or an inconsistency among processing results of the plurality of data processing circuits. A processing error that is generated in any of the plurality of data processing circuits is detected based on a judgment of inconsistency among the processing results provided by the judging circuit.

### BACKGROUND OF THE INVENTION

1. Field of the Invention

The present invention relates to integrated circuits, and more particularly to an integrated circuit that is provided with a redundancy circuit to improve reliability in its operation.

2. Description of the Related Art

It goes without saying that it is desirous for each and every apparatus and system to operate in a stable manner for a long time without error. In particular, apparatus and system reliability has significant importance for apparatuses and systems that are provided in places which cannot be readily accessed or that require time consuming repair and recovery work, such as, for example, equipment that is mounted on artificial satellites and nuclear reactor apparatuses. Apparatus and system reliability-also has significant importance for apparatuses and systems where a malfunction may result in serious consequences and substantial damages, such as, for example, medical equipment and equipment mounted on airplanes. For example, equipment mounted on artificial satellites and high altitude airplanes cannot avoid the influence of neutrons in the cosmic rays. Due to the influence of such cosmic rays, malfunctions of “equipment mounted on artificial satellites” and “equipment mounted on airplanes” may occur. It is important for the equipment to operate in a stable manner and maintain its reliability even under such influences.

In terms of systems, a system may be duplicated to create a redundancy by providing a backup circuit or a backup apparatus. Conventionally, when a malfunction, accident or breakdown occurs in a system, a countermeasure is taken to switch to the backup system to secure the reliability.

In the meantime, it goes without saying that the reliability of an apparatus or a system depends on the reliability of each element included in the apparatus or system and it is therefore important to improve the reliability of each element in order to improve the reliability of the entire apparatus or system, and to reduce the occurring frequency of malfunctions, accidents and failures.

With respect to integrated circuits that are one type of electronic circuit component, the improvement of their reliability has been conventionally sought through improvement of accuracy in their management and testing methods, improvement of sealing means for integrated circuits, and optimization of sealing material. However, there is a certain limitation in the improvements in the reliability that is achieved by such methods. Also, there is a problem in that malfunctions caused by external factors such as noise cannot be prevented even by improving the quality of integrated circuits themselves. Moreover, the idea of improving the reliability through duplicating elements to provide a redundancy in the circuit has not been implemented in conventional integrated circuits.

As seen from the above, to improve the reliability of an apparatus or a system, an improvement of the reliability of each element thereof is indispensable. With respect to integrated circuits, the improvement of their reliability has been conventionally sought through improvement of accuracy in their management and testing methods, improvement of a sealing means for integrated circuits, and optimization of sealing material. However, there is a problem in that there is a certain limitation in such methods, and malfunctions caused by external factors such as noise cannot be accommodated.

It is an advantage of the present invention to provide an integrated circuit that readily solves these problems by providing a circuit structure of the integrated circuit with a redundancy circuit, having an improved reliability by providing a function to self-detect malfunctions and a function to correct errors.

### SUMMARY OF THE INVENTION

To achieve the advantage described above, in accordance with the present invention an integrated circuit includes a plurality of data processing means that perform an identical processing operation; and a judging means that judges a consistency or an inconsistency among processing results of the plurality of data processing means, wherein a processing error that is generated in any of the plurality of data processing means is detected based on a judgment of inconsistency among the processing results provided by the judging means.

Also, in accordance with the present invention there is provided a first delay means that delays input data and/or a clock cycle to have the plurality of data processing means perform the identical processing operations at processing times being shifted from one another, and a second delay means that delays data of the processing results of the plurality of data processing means to be simultaneously inputted in the judging means.

In accordance with the present invention an integrated circuit includes a plurality of data processing means that perform an identical processing operation; and a majority decision means that makes a majority decision on processing results of the plurality of data processing means, wherein a processing error that is generated in any of the plurality of data processing means is corrected through a majority decision processing by the majority decision means.

Furthermore, in accordance with the present invention there is provided a first delay means that delays input data and/or a clock cycle to have the plurality of data processing means perform the identical processing operations at processing times being shifted from one another, and a second delay means that delays data of the processing results of the plurality of data processing means to be simultaneously inputted in the majority decision means.

In this manner, by providing an integrated circuit with a redundancy circuit, an integrated circuit which can achieve a detection of processing error that occurs in any of the plurality of data processing circuits, and substantially improves the reliability in data processing through repeating processing can be realized. Also, an integrated circuit in which a processing error that occurs in any of the plurality of data processing circuits can be automatically recovered according to a majority decision logic, and which substantially improves the reliability in data processing can be realized. Also, by shifting operation timings, a structure that is difficult to be affected by external noises can be realized, and the reliability in this respect can also be improved.

Furthermore, this redundancy circuit has an advantage that the redundancy circuit is complete and is able to used compatibily. Therefore, the redundancy circuit can be substituted, and it is not necessary for the user to be conscious of using the redundancy circuit.

### BRIEF DESCRIPTION OF THE DRAWINGS

FIG. 1 shows a block diagram of a base circuit of an integrated circuit in accordance with the present invention.

FIG. 2 shows a block diagram of an integrated circuit in accordance with another embodiment of the present invention.

FIG. 3 shows a waveform diagram of each section of the integrated circuit shown in FIG. 2.

FIG. 4 shows a block diagram of an integrated circuit in accordance with still another embodiment of the present invention.

FIG. 5 shows a table of truth values of the corresponding sections of the integrated circuit shown in FIG. 4.

FIG. 6 shows a block diagram of an integrated circuit in accordance with yet another embodiment of the present invention.

FIG. 7 shows a waveform diagram of each section of the integrated circuit shown in FIG. 6.

FIG. 8 shows combinations and probability of the circuit errs by the integrated circuit shown in FIG. 4.

### DETAILED DESCRIPTION OF THE PREFERRED EMBODIMENTS

An integrated circuit in accordance with the present invention is described below with reference to the accompanying drawings.

FIG. 1 shows a block diagram of a base circuit of the integrated circuit (IC) in accordance with an embodiment of the present invention. In the present embodiment, a plurality of circuits whose reliability is desired to be improved are disposed within the same IC, and placed under the same operation. Results of the operations are judged, and the next operation is started only when the results are consistent with one another, thereby improving the reliability.

Referring to FIG. 1, a circuit (A) 11 and a circuit (B) 12 are identical processing circuits that perform the same operation. The processing circuit may be any circuit, such as, an operation circuit, a memory circuit, a buffer circuit or a microcomputer, and is not particularly limited. The same input signal 14 is inputted to the circuit (A) 11 and the circuit (B) 12. An output (A) 15 and an output (B) 16 of the circuit (A) 11 and the circuit (B) 12, respectively, are inputted to a two-input EXOR (exclusive OR) gate 13, and an output of the EXOR gate 13 is an output for judgment 17. The output of the EXOR gate 13 is “0” when the values on its input terminals are the same, and “1” when the values on its input terminals are different from each other.

Therefore, only when the value of the judgment output 17 is “0” which is provided when the circuit (A) 11 and (B) 12 output the same values for the same input 14, the next operation is started. When the value of the judgment output 17 is “1”, the circuit (A) 11 and the circuit (B) 12 are made to repeat the same operation.

By this, a correct result can be expected as long as the circuit (A) 11 and the circuit (B) 12 do not err. When the error probability of each of the circuits (A) 11 and (B) 12 is 1/n, the probability p1 in which a two-circuit redundant circuit composed of the circuit (A) 11 and the circuit (B) 12 makes an error judgment is as follows, if the detected error is perfectly corrected:

p1=(1/n)² (1)

which means a substantial improvement in the reliability.

However, there is a possibility that the circuits may overlook an error in the judgment if the two circuits simultaneously err when both of the circuits (A) 11 and (B) 12 are simultaneously affected by an external noise.

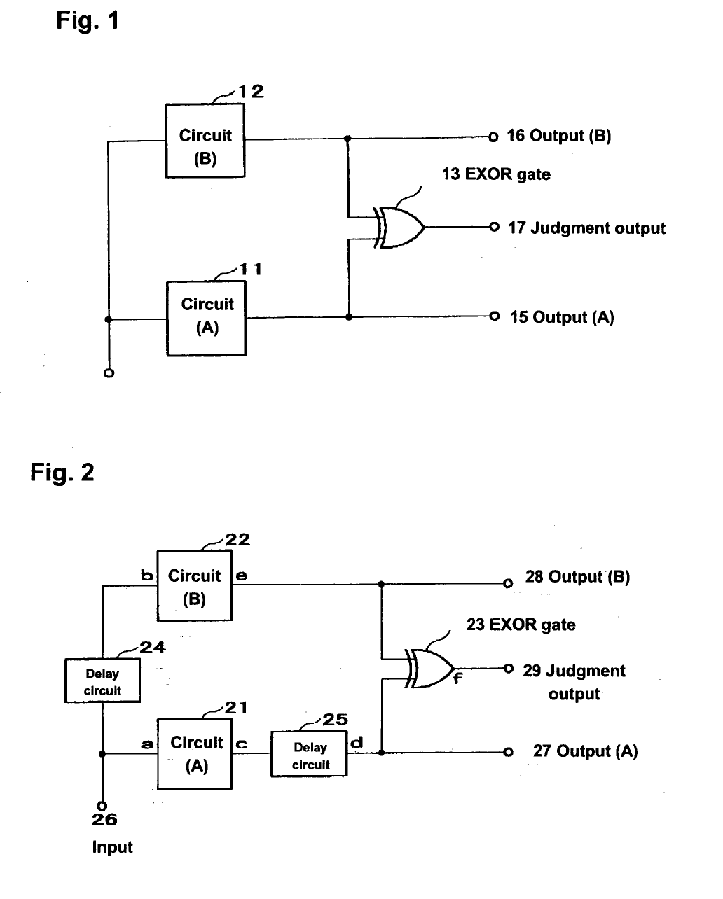

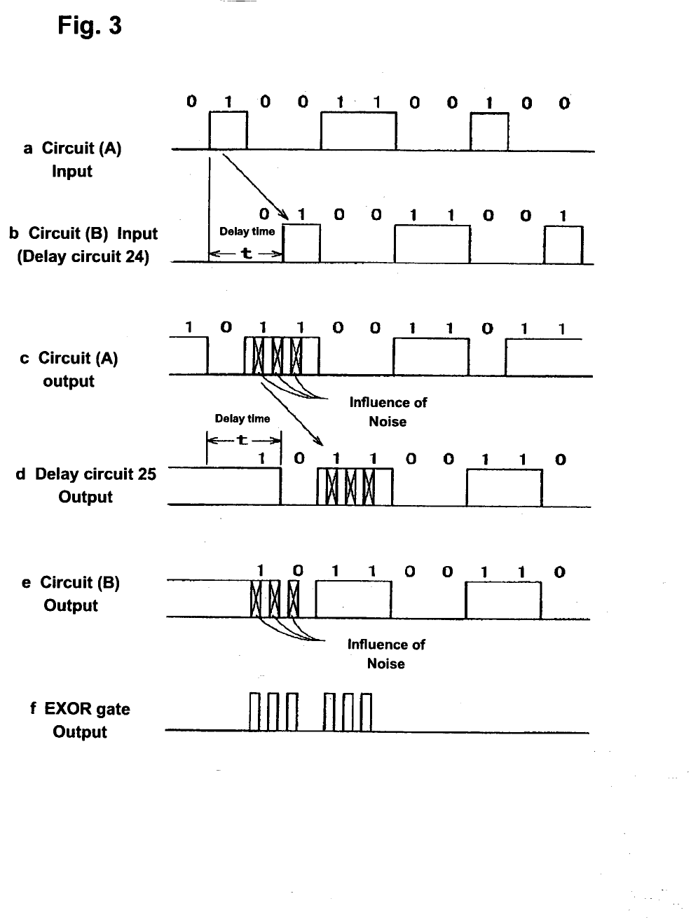

This type of problem can be coped with by time-wise shifting operations of the multiple circuits. An integrated circuit that is provided with a noise countermeasure in accordance with a second embodiment of the present invention is shown in a block diagram of FIG. 2. Also, FIG. 3 shows a waveform of each section of the integrated circuit. In FIG. 3, delays in operation processing in a circuit (A) 21, a circuit (B) 22 and an EXOR gate 23 are deemed to be negligible.

In FIG. 2, the circuit (A) 21 and the circuit (B) 22 are identical circuits that perform the same operation like the embodiment shown in FIG. 1. They are not limited to a particular processing, but presumed to perform an operation of inverting an input and outputting the result. An input signal 26 having a waveform a in FIG. 3 (successive numerical values 0, 1, 0, 0, 1, 1, 0, 0, 1, 0, 0, . . . in FIG. 3) is directly inputted in the circuit (A) 21. An input signal 26 having a waveform b in FIG. 3 which is delayed by a time t by a delay circuit 24 is inputted in the circuit (B) 22.

As shown in FIG. 3, an output of the circuit (A) 21 has a waveform c that is an inverted waveform of that of the input signal 26 (successive numerical values 1, 0, 1, 1, 0, 0, 1, 1, 0, 1, 1, . . . in FIG. 3), and this signal is delayed by a delay circuit 25 by a time t and outputted as an output (A) 27 having a waveform d as shown in FIG. 3. In the meantime, an output of the circuit (B) 22 has a waveform e that is an inverted waveform of the waveform b, and outputted as an output (B) 28. Then, the output (A) 27 and the output (B) 28 are inputted in a two-input EXOR gate 23, and the EXOR gate 23 provides an output for judgment 29.

The output (A) 27, i.e., the waveform d in FIG. 3, and the output (B) 28, i.e., the waveform e in FIG. 3 are identical as long as there is no error or noise because their delay t is the same, although one of them is delayed at its output and the other at its input, and a judgment output 29 that is an output of the EXOR gate is “0”.

Let us consider a case when similar noise simultaneously affect the circuit (A) 21 and the circuit (B) 22. By the noise, let us presume that the waveform c in FIG. 3 that is an output of the circuit (A) 21 and the waveform e in FIG. 3 that is an output of the circuit (B) 22 have noise influences as indicated by “x” marks. The waveforms have these noise influences, and while the waveform e in FIG. 3 is directly inputted in the EXOR gate 23, the waveform c in FIG. 3 is delayed by a time t and inputted in the EXOR gate 23. Accordingly, the noise influences do not simultaneously appear on the inputs to the EXOR gate 23, and they appear in a certain time interval on a judgment output 29 of the EXOR gate 23, thereby generating a waveform f shown in FIG. 3. Therefore, occurrence of noise can be judged by the judgment output 29. Only when the judgment output 29 is “0” which means that the results match with each other, the next operation starts. When the results do not match with each other, the operation is returned to a point where the results match, and the operation is repeated, thereby improving the reliability.

In the embodiments shown in FIGS. 1 and 2, each of the circuits has 1 bit for its input and output. However, needless to say, the present embodiment is also applicable to cases where each of the circuits has multiple parallel bits for its input and output and a matching judgment is conducted for each bit. In this case, judgment results of all the bits can be outputted in one-bit judgment of consistency or inconsistency.

The embodiments described above adopt a method in which an error is judged within the integrated circuit, and the error is corrected by repeating an operation. However, when it is difficult to reproduce an operation or an operation must be completed in a short time, the execution of repeated operations is not desirous. This problem can be solved by providing multiple circuits with a majority judgment circuit and providing a function to have the circuits automatically correct errors.

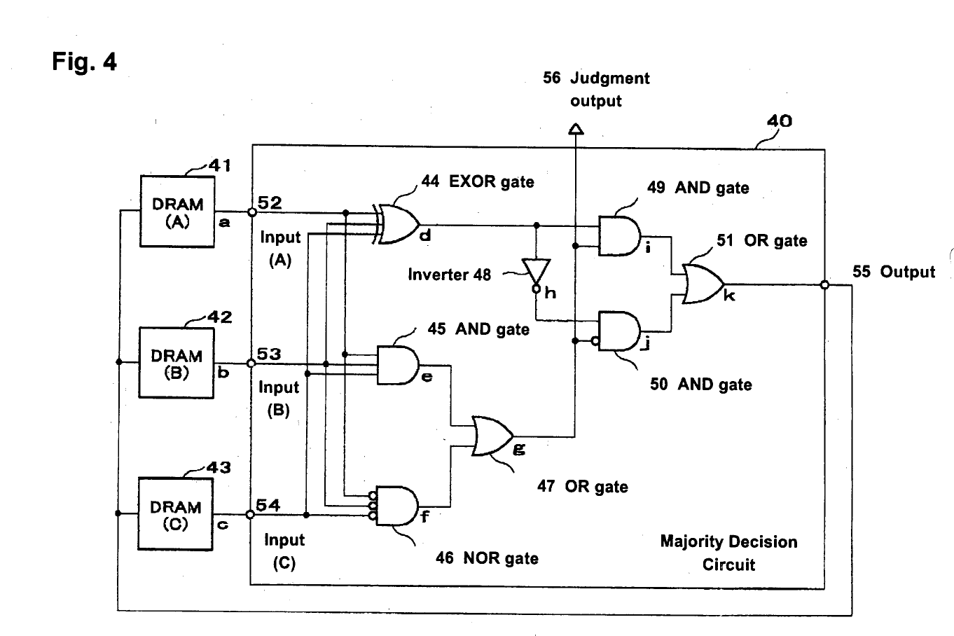

FIG. 4 shows a circuit block diagram of an integrated circuit having an automatic correction function by using a majority decision judgment in accordance with a third embodiment of the present invention.

FIG. 4 shows an example in which the present invention is applied to refresh circuit of a DRAM (Dynamic Random Access Memory).

Let us presume that DRAM (A) 41, DRAM (B) 42 and DRAM (C) 43 store identical data, and are refreshed at a predetermined time interval. Read refresh data (a, b and c in FIG. 4) from the DRAM (A) 41, DRAM (B) 42 and DRAM (C) 43 are three inputs, i.e., an input (A) 52, an input (B) 53 and an input (C) 54 to a majority decision circuit 40, respectively.

The majority decision circuit 40 is composed of a three-input EXOR gate 44, a three-input AND gate 45, a three-input NOR gate 46, a two-input OR gate 47, an inverter 48, a two-input AND gate 49, a one-input inversion type two-input AND gate 50, and a two-input OR gate 51. A portion including the two-input AND gate 49, one-input inversion type two-input AND gate 50, and two-input OR gate 51 forms a so-called multiplexer circuit; however, the inverter 48 and the two-input AND gate 49 may be replaced with a two-input NOR gate.

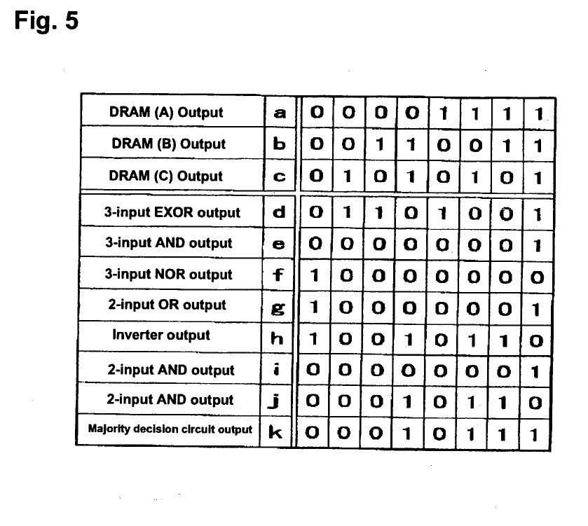

FIG. 5 shows a table of truth values at sections (d k in FIG. 4) of the majority decision circuit 40 with respect to read refresh data a, b and c from the DRAM (A) 41, DRAM (B) 42 and DRAM (C) 43. It is clear from FIG. 5 that a majority decision circuit output 55 provides a value to the read refresh data (a, b and c in FIGS. 4 and 5). This data is inputted as a write refresh data in the DRAM (A) 41, DRAM (B) 42 and DRAM (C) 43. By this, even when any of the outputs of the three DRAMs contains an error, the error is corrected by the majority decision, which substantially improves the circuit's reliability. A buffer circuit for adjusting the timing may be inserted between the majority decision circuit output 55 and the inputs to the DRAM (A) 41, DRAM (B) 42 and DRAM (C) 43. An output (g in FIG. 5) of the OR gate 47 can be used as a matched judgment output 56. In this case, when data of the three circuits match with one another, the output is “1”.

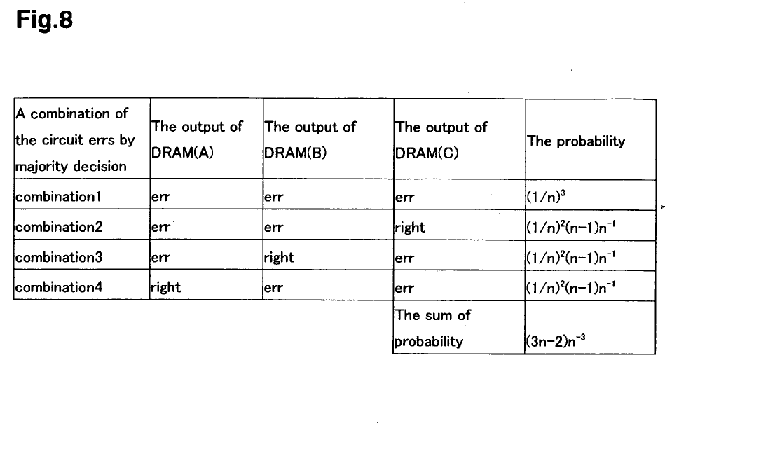

The probability p2 in which this circuit errs in its judgment concurs with a probability in which any two of the outputs of the three DRAMs are erroneous. Therefore the probability p2 is given by the sum of each probability of the combinations in FIG. 8, and is as follows, if an error probability of each of the DRAMs is 1/n:

p2=(3n−2)n⁻³ (2)

Where, 1/n<½

p2<1/n (3)

The majority decision circuit 40 is not limited to the example shown in FIG. 4, and any type of circuit may be applicable if a majority decision circuit output k shown in FIG. 5 is outputted for read refresh data a, b and c. This example explains a refresh circuit for DRAMs. However, the DRAMs in FIG. 4 may be replaced with identical processing circuits of another type, and a majority decision circuit output may be provided. Such a structure can provide for a highly reliable data processing circuit. The number of DRAMs in FIG. 4 is 3, but the number of identical processing circuits may be any number that is three or greater. However, circuits in an even number may cause confusion since a majority decision may have to be made, and therefore circuits in an odd number may be desirous.

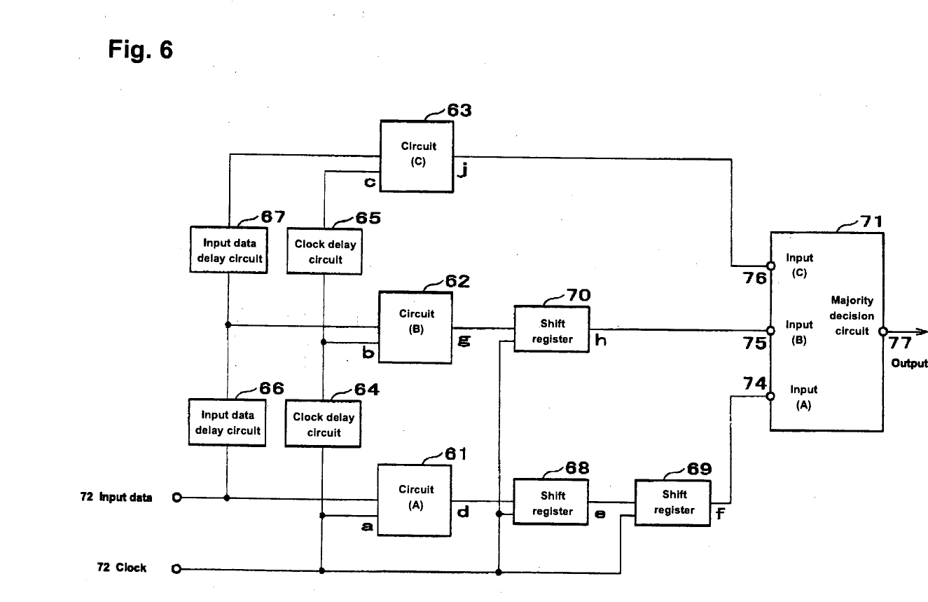

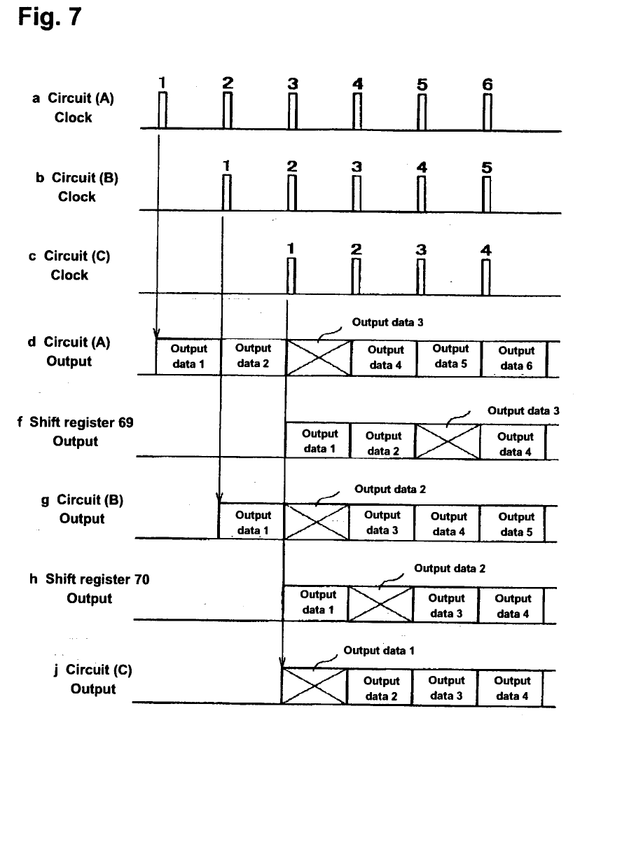

FIG. 6 shows a block diagram of an integrated circuit in accordance with a fourth embodiment of the present invention. This embodiment is one in which the third embodiment is provided with a noise countermeasure like the second embodiment. Also, FIG. 7 shows waveforms of respective sections of the integrated circuit. For the sake of easy understanding, FIG. 7 omits clocks before a clock 1, and output data before output data 1.

In FIG. 6, a circuit (A) 61, circuit (B) 62 and circuit (C) 63 are identical circuits that perform a predetermined operation on inputted data in synchronism with a clock. Clock delay circuits 64 and 65 each delay an inputted clock by one clock cycle and output the same. Also, input delay circuits 66 and 67 each delay inputted data by one clock cycle and output the same. Also, shift registers 68, 69 and 70 each delay an output data inputted from a circuit by one clock cycle and output the same. A majority decision circuit 71 is similar to the majority decision circuit 40 shown in FIG. 4.

Accordingly, a clock (b in FIG. 7) inputted in the circuit (B) 62 is delayed by one clock cycle by the clock delay circuit 64 with respect to a clock (a in FIG. 7) inputted in the circuit (A) 61. Also, although not shown in FIG. 7, an input data inputted in the circuit (B) 62 is delayed by one clock cycle by the input data delay circuit 66 with respect to an input data inputted in the circuit (A) 61.

Similarly, a clock (c in FIG. 7) inputted in the circuit (C) 63 is delayed by the clock delay circuit 65 by one clock cycle with respect to the clock (b in FIG. 7) inputted in the circuit (B) 62, and delayed by two clock cycles with respect to the clock inputted in the circuit (A) 61. Also, an input data inputted in the circuit (C) 63 is delayed by two clock cycles by the input data delay circuits 66 and 67 with respect to an input data inputted in the circuit (A) 61.

As a result, output data (g in FIG. 7) of the circuit (B) 62 is outputted one clock cycle delayed than an output (d in FIG. 7) of the circuit (A) 61, and output data 0 in FIG. 7) of the circuit (C) 63 is outputted two clock cycles delayed than the output (d in FIG. 7) of the circuit (A) 61.

Then, the output data (d in FIG. 7) of the circuit (A) 61 is delayed by two clock cycles by the shift register 68 and the shift register 69 and inputted in the majority decision circuit 71, and the output data (g in FIG. 7) of the circuit (B) 62 is delayed by one clock cycle by the shift register 70 and inputted in the majority decision circuit 71. By this processing, due to delays in the clocks and input data and delays in the output data, the outputs from the three circuits, i.e., the circuit (A) 61, circuit (B) 62 and circuit (C) 63 are synchronized and inputted in the majority decision circuit 71.

If the circuit (A) 61, circuit (B) 62 and circuit (C) 63 are simultaneously exposed to an external noise, for example, its influence may simultaneously occur on the output waveform (d in FIG. 7) of the circuit (A), output waveform (g in FIG. 7) of the circuit (B) and output waveform (j in FIG. 7) as indicated by “x”.

However, delays are generated thereafter and cause waveforms f, h and j shown in FIG. 7, and therefore the noise influences are inputted in the majority decision circuit 71 at different times. Accordingly, portions that are affected by the noise are recovered by other signals according to the majority decision logic, and the influences of external noise is removed from the output of the majority decision circuit 71.

In the description above, each of the clock delay circuits 64 and 65, the input data delay circuits 66 and 67 and the shift registers 68, 69 and 70 creates a delay of one clock cycle. However, without being limited to this, any identical delay times that are longer than the duration of the noise can be selected.

As described above, in accordance with the present invention, since an integrated circuit is provided with a redundancy circuit, the integrated circuit which can achieve a detection of a processing error that occurs in any of a plurality of data processing circuits, and substantially improves the reliability in data processing through repeat processing can be realized. Also, an integrated circuit in which a processing error that occurs in any of the plurality of data processing circuits can be automatically recovered according to a majority decision logic, and which substantially improves the reliability in data processing can be realized. Also, a time shifting operation, a structure that is difficult to be affected by external noises can be realized, and the reliability in this respect can also be improved. Furthermore, this redundancy circuit has an advantage that the redundancy circuit is complete and is able to be used compatibily. Therefore, the redundancy circuit can be substituted. It is not necessary for a user to be conscious of using the redundancy circuit. Accordingly, the use of the redundancy circuit in a broad range of applications where a high reliability is required can be expected.

What is claimed is:

1. An integrated circuit comprising:
a plurality of data processing circuits that each performs an identical processing operation; and
a judging circuits that judges a consistency or an inconsistency among processing results of the plurality of data processing circuits,
wherein a processing error that is generated in any of the plurality of data processing circuits is detected based on a judgment of inconsistency among the processing results provided by the judging circuit.

2. The integrated circuit according to claim 1, further comprising a first delay circuit that delays input data and/or a clock cycle to have the plurality of data processing circuits perform the identical processing operations at processing times being shifted from one another, and a second delay circuit that delays data of the processing results of the plurality of data processing circuits to be simultaneously inputted in the judging circuit.

3. An integrated circuit comprising:
a plurality of data processing circuits that each performs an identical processing operation; and
a majority decision circuits that makes a majority decision based on processing results of the plurality of data processing circuits,
wherein a processing error that is generated in any of the plurality of data processing circuits is corrected by a majority decision result from the majority decision circuit.

4. An integrated circuit according to claim 3, comprising a first delay circuit that delays input data and/or a pulse cycle to have the plurality of data processing circuits perform the identical processing operations at processing times being shifted from one another, and a second delay circuit that delays data of the processing results of the plurality of data processing circuits to be simultaneously inputted in the majority decision circuit.

5 The integrated circuit according to claim 1, wherein the data processing circuits are memory circuits.

6. The integrated circuit according to claim 1, wherein the data processing circuits are buffer circuits.

7. The integrated circuit according to claim 1, wherein the data processing circuits are microprocessor circuits.

8. The integrated circuit according to claim 3, wherein the data processing circuits are memory circuits.

9. The integrated circuit according to claim 3, wherein the data processing circuits are buffer circuits.

10. The integrated circuit according to claim 3, wherein the data processing circuits are microprocessor circuits.

11. The integrated circuit according to claim 1, wherein the judging circuit includes an exclusive OR gate.

12. The integrated circuit according to claim 3, wherein the judging circuit includes an exclusive OR gate.

13. An integrated circuit comprising:
means for performing a plurality of identical processing operations; and
means for judging a consistency or an inconsistency among processing results from the means for performing a plurality of identical processing operations,
wherein a processing error that is generated by the means for performing a plurality of identical processing operations is detected based on a judgment of inconsistency among processing results provided by the means for judging.

14. An integrated circuit comprising:
means for performing a plurality of identical processing operations; and
means for making a majority decision based on processing results from the means for performing a plurality of identical processing operations,
wherein a processing error that is generated by the means for performing a plurality of identical processing operations is corrected by a majority decision result from the means for making a majority decision.

15. The integrated circuit according to claim 13, wherein the means for performing a plurality of identical processing operations are memory circuits.

16. The integrated circuit according to claim 13, wherein the means for performing a plurality of identical processing operations are buffer circuits.

17. The integrated circuit according to claim 13, wherein the means for performing a plurality of identical processing operations are microprocessor circuits.

18. The integrated circuit according to claim 14, wherein the means for performing a plurality of identical processing operations are memory circuits.

19. The integrated circuit according to claim 14, wherein the means for performing a plurality of identical processing operations are buffer circuits.

20. The integrated circuit according to claim 14, wherein the means for performing a plurality of identical processing operations are microprocessor circuits.

21. A method for providing redundancy in an integrated circuit comprising:
performing a plurality of identical processing operations;
judging a consistency or inconsistency in processing results of the plurality of identical processing operations; and
detecting a processing error that is generated in any of the plurality of identical processing operations based on a judgment of inconsistency in the processing results.
